(19) United States
(12) Patent Application Publication
(10) Pub. No.: US 2007/0020877 A1
(43) Pub. Date: Jan. 25, 2007

(54) Shallow trench isolation structure and method of fabricating the same

(75) Inventors: Uway Tseng, Dong-Shi Town (TW); Ching-Yu Chang, Yuansun Village (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Taiwan Semiconductor Manufacturing Co., Ltd.

(21) Appl. No.: 11/186,360

(22) Filed: Jul. 21, 2005

(51) Int. Cl. H01L 21/76

(52) U.S. Cl. 438/424

(57) ABSTRACT

A shallow trench isolation structure has a trench formed in a substrate, a silicon oxynitride layer conformally formed on the sidewalls and bottom of the trench, and a high density plasma (HDP) oxide layer substantially filling the trench.

### BACKGROUND

The present invention relates to semiconductor integrated circuits, and more specifically to a shallow trench isolation structure and a method of fabricating the same.

As integration density of semiconductor integrated circuits increases, circuit components, such as transistors, are formed closer to each other and their reliability may be reduced unless effective isolation techniques for separating devices, such as MOS transistors, are employed. A trench isolation technique which can form an isolation region having a narrow width is widely used in the fabrication of a highly integrated semiconductor device.

FIG. 1 is a cross section of a conventional trench isolation structure. The structure shown includes a semiconductor substrate 100 with a trench 102 formed therein, a thermal oxide liner 104 formed on the sidewalls and bottom of the trench 102, a high density plasma (HDP) oxide liner 106 conformally formed on the thermal oxide liner 104, and a HDP oxide layer 108 filling the trench 102.

The thermal oxide liner 104 conformally formed on the inner walls of the trench 102 releases stress generated from the silicon substrate 100. The thermal oxide liner 104, however, consumes silicon substrate 100 during thermal oxidation. Thus, a thin thermal oxide liner is required to reduce silicon loss of the substrate 100.

The HDP oxide liner 106 serves as a protective layer to avoid plasma damage to the silicon substrate 100 during subsequent high density plasma chemical vapor deposition (HDPCVD). A sufficiently thick HDP oxide liner 106 formed on the thermal oxide liner 104 is required to effectively resist plasma due to loose oxide structure and the thin thermal oxide liner 104. The inner space of the trench 102 is thus significantly narrowed, deteriorating trench filling performance.

Additionally, when using phosphoric acid (H₃PO₄) or hydrofluoric acid (HF) to remove a pad layer (not shown), a portion of the HDP oxide liner 106 is etched simultaneously due to lack of resistance thereto, causing concave defects at the trench corner 110, negatively affecting electrical performance of elements.

Thus, a trench isolation structure with improved filling performance and level surface at corners is desirable. Also, the silicon substrate can be protected from HDPCVD plasma during fabrication.

### SUMMARY

The invention provides a trench isolation structure comprising a trench formed in a substrate, a silicon oxynitride layer conformally formed on the sidewalls and bottom of the trench, and a high density plasma (HDP) oxide layer substantially filling the trench.

The invention also provides a method of fabricating a trench isolation structure. A substrate with a trench therein is provided. An oxide liner is formed on the substrate and the sidewalls and bottom of the trench. A silicon oxynitride layer is formed on the substrate and the sidewalls and bottom of the trench. An oxide layer is formed on the silicon oxynitride layer and is filled in the trench by high density plasma chemical vapor deposition (HDPCVD).

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a cross section of a conventional trench isolation structure;

FIGS. 2A˜2G are cross sections of a method of fabricating a trench isolation structure of the invention; and

FIGS. 3A˜3G are cross sections of another method of fabricating a trench isolation structure of the invention.

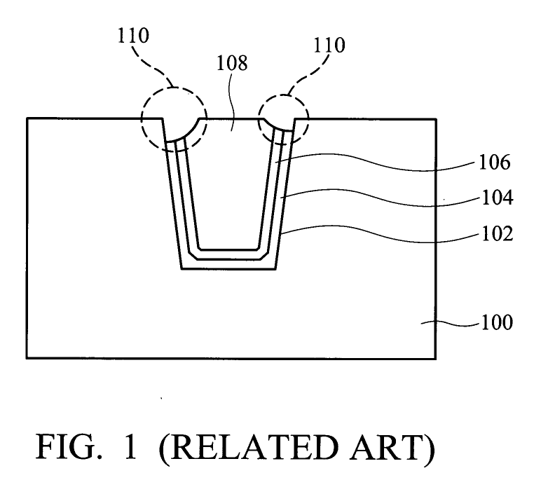

### DESCRIPTION

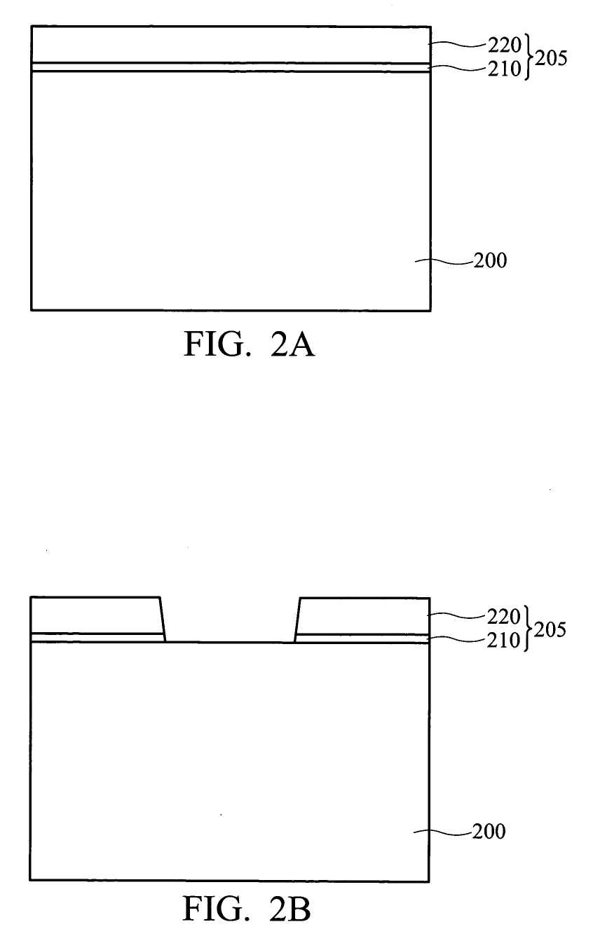

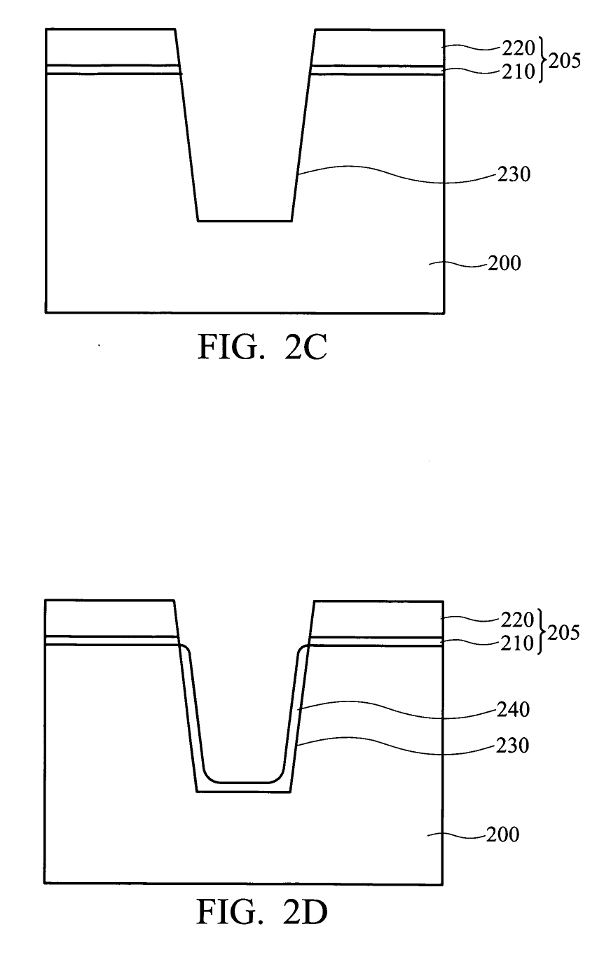

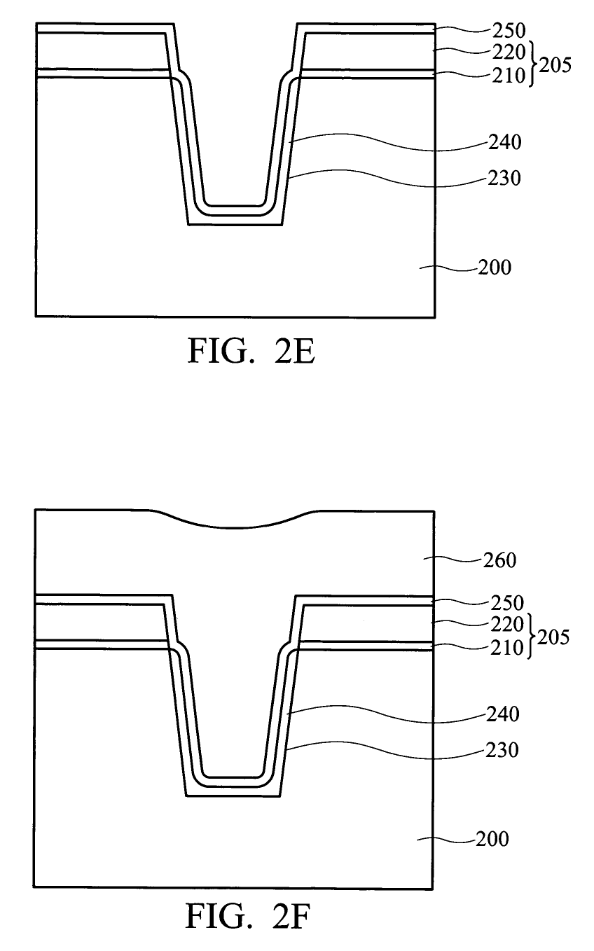

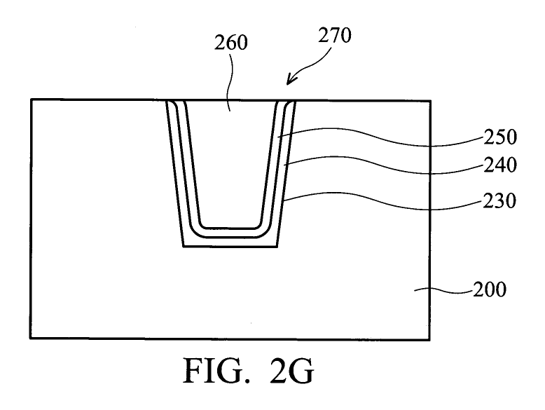

FIGS. 2A˜2G are cross sections of the method of fabricating a trench isolation structure according to the invention.

Referring to FIG. 2A, a semiconductor substrate 200, such as P-type, N-type, or epitaxy silicon substrate, is provided and a pad layer 205 is formed thereon by chemical vapor deposition (CVD) or thermal oxidation. The pad layer 205 comprises a pad oxide layer 210 and a pad nitride layer 220 overlying the pad oxide layer 210. Next, the pad layer 205 is patterned by photolithography and etching to expose an area where a trench isolation region is to be formed in the semiconductor substrate 200, as shown in FIG. 2B.

The semiconductor substrate 200 is subsequently etched using the patterned pad layer 205 as a mask to form a trench 230, as shown in FIG. 2C. Next, an oxide liner 240 is grown on the sidewalls and bottom of the trench 230 by thermal oxidation, as shown in FIG. 2D.

Subsequently, a silicon oxynitride layer 250 is conformally formed on the pad layer 205 and the oxide liner 240 by high density plasma chemical vapor deposition (HDPCVD) using N₂, O₂, and SiH₄ as reactants without sputtering, as shown in FIG. 2E. The silicon oxynitride layer 250 is oxygen rich and has a thickness of about 10˜150 Å and a K value of about 0.5˜1, preferably 0.7.

Next, referring to FIG. 2F, an oxide layer 260 is deposited on the silicon oxynitride layer 250 and substantially fills the trench 230 by HDPCVD using O₂ and SiH₄ as reactants with Ar sputtering.

The semiconductor substrate 200 covered by the silicon oxynitride layer 250 is completely protected from HDPCVD plasma. The thin silicon oxynitride layer 250 is sufficient to resist plasma due to a dense structure comprising oxygen and nitrogen atoms. The inner space of the trench 230 is thus enlarged, improving trench filling performance.

Finally, chemical mechanical polishing (CMP) is performed to planarize the uneven HDP oxide layer 260, exposing the pad layer 205. The CMP may include slurry-based CMP or fixed abrasive CMP. Subsequently, a rapid thermal annealing procedure is performed at 900° C. for about 15˜30 min to increase the mechanical robustness of the entire trench isolation structure.

The pad nitride layer 220 and the pad oxide layer 210 are then removed by wet etching using appropriate etching solutions, such as phosphoric acid (H₃PO₄) at about 160° C. and hydrofluoric acid (HF) at room temperature, respectively. Accordingly, the trench isolation structure 270 of the invention is achieved, as shown in FIG. 2G.

Oxygen rich Silicon oxynitride layer has higher etching selectivity with silicon nitride layer in phosphoric acid (H₃PO₄). Thus, the pad nitride layer 220 and the oxygen rich silicon oxynitride layer 250 have a high etching selectivity ratio of at least 10:1 in phosphoric acid (H₃PO₄) . Also, in hydrofluoric acid (HF), is the pad oxide layer 210 has a higher etching rate than the silicon oxynitride layer 250. Namely, the silicon oxynitride layer 250 has higher etching resistance to phosphoric acid (H₃PO₄) and hydrofluoric acid (HF) than the pad nitride layer 220 and the pad oxide layer 210, respectively. Thus, the trench corner remains complete after wet etching, avoiding concave defects.

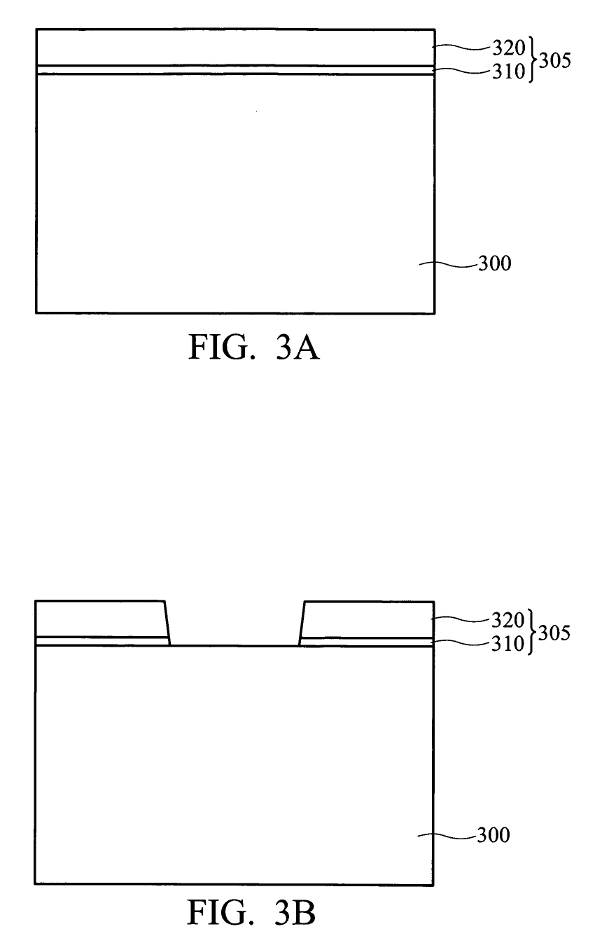

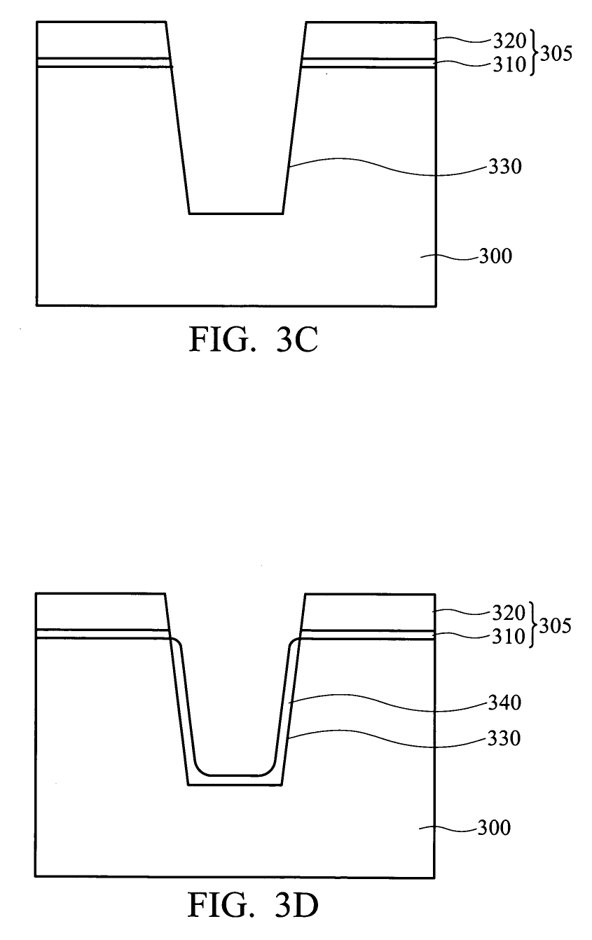

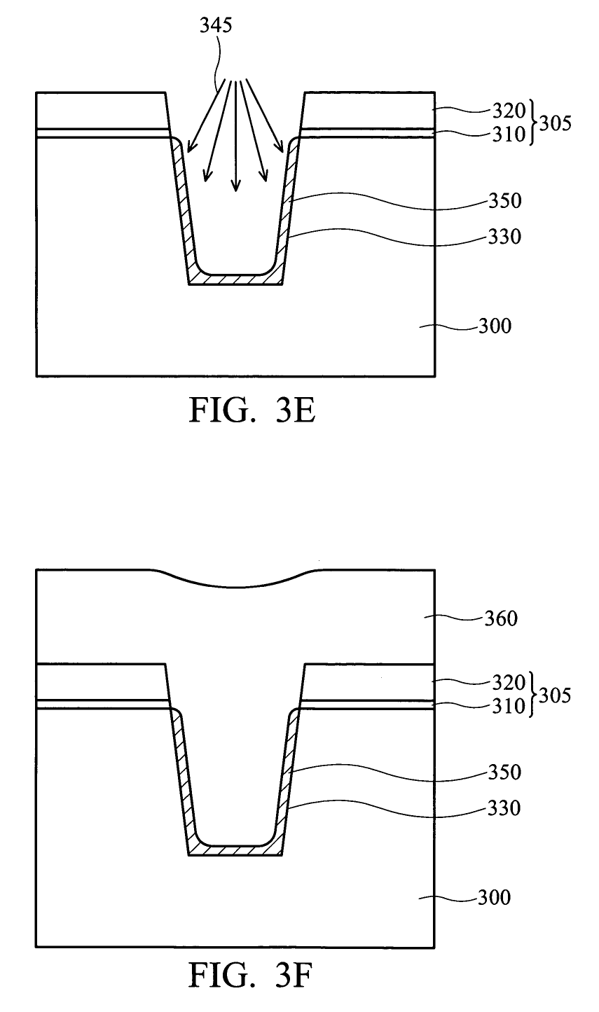

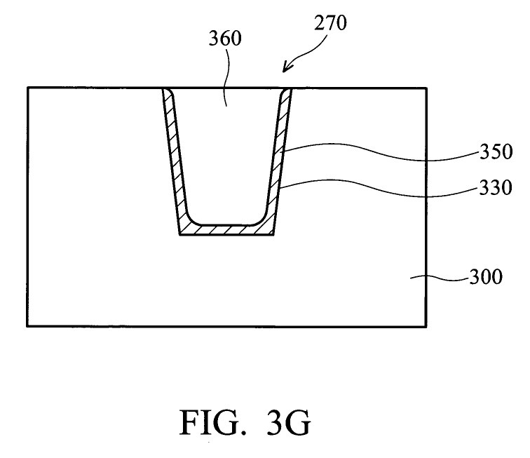

FIGS. 3A˜3G are cross sections of another method of fabricating a trench isolation structure according to the invention. The distinction between FIGS. 3A˜3G and FIGS. 2A˜2G is the formation of the silicon oxynitride layers 250 and 350.

Referring to FIG. 3A, a semiconductor substrate 300, such as P-type, N-type, or epitaxy silicon substrate, is provided and a pad layer 305 is formed thereon by chemical vapor deposition (CVD) or thermal oxidation. The pad layer 305 comprises a pad oxide layer 310 and a pad nitride layer 320 overlying the pad oxide layer 310. Next, the pad layer 305 is patterned by photolithography and etching to expose an area of the semiconductor substrate 300, a trench isolation region to be formed, as shown in FIG. 3B.

The semiconductor substrate 300 is subsequently etched using the patterned pad layer 305 as a mask to form a trench 330, as shown in FIG. 3C. Next, an oxide liner 340 is grown on the sidewalls and bottom of the trench 330 by thermal oxidation, as shown in FIG. 3D.

Subsequently, nitrogen atoms are implanted into the oxide liner 340 to form a silicon oxynitride layer 350 by nitrogen plasma treatment 345, as shown in FIG. 3E. The silicon oxynitride layer 350 is oxygen rich and has a thickness of about 10˜150 Å and a K value of about 0.5˜1, preferably 0.7. The nitrogen source of the plasma treatment 345 may comprise N-based gas, such as nitrogen gas (N₂), nitric oxide gas (NO), nitrous oxide (N₂O), nitrite gas (NO₂), or nitrate gas (NO₃), preferably nitrogen gas (N₂) or nitrous oxide (N₂O).

Next, referring to FIG. 3F, an oxide layer 360 is deposited on the silicon oxynitride layer 350 and is filled in the trench 330 by HDPCVD using O₂ and SiH₄ as reactants with Ar sputtering.

The silicon oxynitride layer 350 is directly formed by implanting nitrogen atoms to the oxide liner 340, without deposition of any nitrogen-containing layer to further resist plasma, providing increased inner space of the trench 330. Also, the dense silicon oxynitride layer 350 protects the semiconductor substrate 300 from HDPCVD plasma.

Finally, chemical mechanical polishing (CMP) is performed to planarize the uneven HDP oxide layer 360, exposing the pad layer 305. The CMP may include slurry-based CMP or fixed abrasive CMP. Subsequently, a rapid thermal annealing procedure is performed at 900° C. for about 15˜30 min to increase the mechanical robustness of the entire trench isolation structure.

The pad nitride layer 320 and the pad oxide layer 310 are then removed by wet etching using appropriate etching solutions, such as phosphoric acid (H₃PO₄) at about 160° C. and hydrofluoric acid (HF) at room temperature, respectively. Accordingly, the trench isolation structure 370 of the invention is achieved, as shown in FIG. 3G.

The invention provides dense and thin silicon oxynitride layers formed by various methods, such as deposition or plasma treatment, to protect semiconductor substrate from HDPCVD plasma and reduce occupied space in a trench simultaneously, improving trench filling performance. Additionally, the silicon oxynitride layer has a higher resistance to etching solutions, such as phosphoric acid (H₃PO₄) and hydrofluoric acid (HF), than the pad layer, such as pad nitride layer and pad oxide layer, so that a trench isolation structure with level corner surface can be formed after etching the pad layer, without concave defects.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. A shallow trench isolation structure, comprising:
a substrate comprising a trench;
a silicon oxynitride layer conformally formed on the sidewalls and bottom of the trench; and
a high density plasma (HDP) oxide layer substantially filling the trench.

2. The shallow trench isolation structure as claimed in claim 1, further comprising an oxide liner interposed between the substrate and the silicon oxynitride layer.

3. The shallow trench isolation structure as claimed in claim 1, wherein the silicon oxynitride layer has a thickness of about 10˜150 Å.

4. The shallow trench isolation structure as claimed in claim 1, wherein the silicon oxynitride layer has a K value of about 0.5˜1.

5. The shallow trench isolation structure as claimed in claim 1, wherein the shallow trench isolation structure is substantially free of concave defects at corners near the surface of the substrate.

6. A method of fabricating a shallow trench isolation structure, comprising:
forming a trench in a substrate;
forming an oxide liner on the sidewalls and bottom of the trench;
forming a silicon oxynitride layer on the substrate and the sidewalls and bottom of the trench; and
forming an oxide layer on the silicon oxynitride layer and substantially filling the trench by high density plasma chemical vapor deposition (HDPCVD).

7. The method as claimed in claim 6, wherein the trench is formed using a patterned pad layer on the substrate as a mask.

8. The method as claimed in claim 7, wherein the pad layer comprises a pad oxide layer and a pad nitride layer overlying the pad oxide layer.

9. The method as claimed in claim 6, wherein the silicon oxynitride layer is formed on the oxide liner by high density plasma chemical vapor deposition (HDPCVD) without sputtering.

10. The method as claimed in claim 6, wherein the silicon oxynitride layer is formed by implanting nitrogen atoms into the oxide liner with nitrogen plasma treatment.

11. The method as claimed in claim 10, wherein the nitrogen plasma treatment has a nitrogen source comprising nitrogen gas (N₂), nitric oxide gas (NO), nitrous oxide (N₂O), nitrite gas (NO₂), or nitrate gas (NO₃).

12. The method as claimed in claim 6, wherein the silicon oxynitride layer has a thickness of about 10˜150 Å.

13. The method as claimed in claim 6, wherein the silicon oxynitride layer has a K value of about 0.5˜1.

14. The method as claimed in claim 8, further comprising, after HDPCVD, planarizing the oxide layer by chemical mechanical polishing (CMP), exposing the pad layer.

15. The method as claimed in claim 14, wherein the pad nitride layer is removed by wet etching using phosphoric acid as an etching solution.

16. The method as claimed in claim 15, wherein the pad nitride layer and the silicon oxynitride layer have an etching selectivity ratio of at least 10:1 in phosphoric acid.

17. The method as claimed in claim 14, wherein the pad oxide layer is removed by wet etching using hydrofluoric acid as an etching solution.

18. The method as claimed in claim 17, wherein the pad oxide layer has a higher etching rate than the silicon oxynitride layer in hydrofluoric acid.

19. The method as claimed in claim 6, wherein the shallow trench isolation structure is substantially free of concave defects at corners.
